(19) United States
(12) Patent Application Publication
(10) Pub. No.: US 2015/0310909 A1
(43) Pub. Date: Oct. 29, 2015

(54) OPTIMIZATION OF CIRCUIT LAYOUT AREA OF A MEMORY DEVICE

(71) Applicant: Broadcom Corporation, Irvine, CA (US)

(72) Inventor: Scott Yu-Fan CHU, San Jose, CA (US)

(73) Assignee: Broadcom Corporation, Irvine, CA (US)

(21) Appl. No.: 14/278,763

(22) Filed: May 15, 2014

Related U.S. Application Data
(60) Provisional application No. 61/984,110, filed on Apr. 25, 2014.

(51) Int. Cl. G11C 11/419

(52) U.S. Cl. CPC G11C 11/419

(57) ABSTRACT

A memory cell including a storage cell, a write port cell, and a read port cell is discussed. The storage cell is configured to store a logic value. The write port cell is configured to write the logic value. The read port cell is configured to read the stored logic value and includes a plurality of read ports. At least a first port of the plurality of read ports includes a first and a second active diffusion region that are each configured to be used for implementation of a second p-channel transistor. At least a second read port of the plurality of read ports includes a third and fourth active diffusion regions that are each configured to be used for implementation of a second n-channel transistor.

### CROSS-REFERENCE TO RELATED APPLICATIONS

This application claims the benefit of provisional application No. 61/984,110, filed on Apr. 25, 2014, which is incorporated herein by reference in its entirety.

### BACKGROUND OF THE DISCLOSURE

### Background Art

A memory is an electronic device for reading and/or writing electronic data. The memory can be implemented as a volatile memory, which requires power to maintain its stored information, or a non-volatile memory, which can maintain its stored information even when not powered. The volatile memory can be implemented as a dynamic random-access memory (DRAM) or a static random-access memory (SRAM) to provide some examples, and non-volatile memory can be implemented as a flash memory or a magnetoresistive random-access memory (MRAM) to provide some examples.

Conventionally, a single port SRAM has been widely used, which allows a read or a write in a single clock cycle. However, multi-port SRAMs are also being used that are capable of performing multiple read and write operations in a single clock cycle. The demand for multi-port SRAMs and other multi-port memory devices is increasing to accommodate high speed communications.

### BRIEF DESCRIPTION OF THE DRAWINGS/FIGURES

The accompanying drawings illustrate the present disclosure and, together with the description, further serve to explain the principles of the disclosure and to enable one skilled in the pertinent art to make and use the disclosure.

FIG. 1 illustrates a block diagram am exemplary memory device;

FIG. 2 illustrates a block diagram of an exemplary memory cell;

FIG. 3 illustrates a schematic diagram of an exemplary a write port cell;

FIG. 4 illustrates a schematic diagram of a first exemplary storage cell;

FIG. 5 illustrates a schematic diagram of a second exemplary storage cell;

FIG. 6 illustrates a schematic diagram of a third exemplary storage cell;

FIG. 7a illustrates a schematic diagram of a prior art read port cell;

FIG. 7b illustrates a conventional circuit layout of the prior art read port cell;

FIG. 8a illustrates a schematic diagram of an exemplary read port cell; and

FIG. 8b illustrates an exemplary circuit layout of the read port cell.

The present disclosure will now be described with reference to the accompanying drawings. In the drawings, like reference numbers generally indicate identical, functionally similar, and/or structurally similar elements. The drawing in which an element first appears is indicated by the leftmost digit(s) in the reference number.

### DETAILED DESCRIPTION OF THE DISCLOSURE

The following Detailed Description refers to accompanying drawings to illustrate one or more embodiments consistent with the present disclosure. The disclosed embodiment(s) merely exemplify the disclosure. The embodiment(s) described, and references in the specification to “one embodiment,” “an embodiment,” “an example embodiment,” “an example of this embodiment,” “an exemplary embodiment,” etc., indicate that the embodiment(s) described may include a particular feature, device, or characteristic, but every embodiment may not necessarily include the particular feature, device, or characteristic. Moreover, such phrases are not necessarily referring to the same embodiment. Further, when a particular feature, device, or characteristic is described in connection with an embodiment, it is within the knowledge of those skilled in the relevant art(s) to effect such feature, device, or characteristic in connection with other embodiments whether or not explicitly described.

The exemplary embodiments described herein are provided for illustrative purposes, and are not limiting. Other exemplary embodiments are possible, and modifications can be made to the exemplary embodiments within the spirit and scope of the disclosure. Therefore, the Detailed Description is not meant to limit the disclosure. Rather, the scope of the disclosure is defined only in accordance with the following claims and their equivalents.

Embodiments of the disclosure can be implemented in hardware, firmware, software, or any combination thereof. Embodiments of the disclosure can also be implemented as instructions stored on a machine-readable medium, which can be read and executed by one or more processors. A machine-readable medium can include any mechanism for storing or transmitting information in a form readable by a machine (e.g., a computing device). For example, a machine-readable medium can include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions can be described herein as performing certain actions. However, it should he appreciated that such descriptions are merely for convenience and that such actions in fact result from computing devices, processors, controllers, or other devices executing the firmware, software, routines, instructions, etc.

The following Detailed Description of the exemplary embodiments will so fully reveal the general nature of the disclosure that others can, by applying knowledge of those skilled in relevant art(s), readily modify and/or adapt for various applications such exemplary embodiments, without undue experimentation, without departing from the spirit and scope of the disclosure. Therefore, such adaptations and modifications are intended to be within the meaning and plurality of equivalents of the exemplary embodiments based upon the teaching and guidance presented herein. It is to he understood that the phraseology or terminology herein is for the purpose of description and not of limitation, such that the terminology or phraseology of the present specification is to be interpreted by those skilled in relevant art(s) in light of the teachings herein.

The logic levels and/or the default voltage states are provided for exemplary purposes only. Those skilled in the art will appreciate that logic levels can be reversed such that transistors are asserted using an active-low or an active-high logic scheme. Similarly, default, pull-up, and/or pull-down voltage states can be modified to accommodate the appropriate logic implementation. Transitions of data lines from one State to another should not be interpreted as an implication that the previous state was a default, standard, static, and/or an unchanging state.

Although the description of the present disclosure is to be described in terms of an SRAM, those skilled in the relevant art(s) will recognize that the present disclosure can be applicable to other types of memory without departing from the spirit and scope of the present disclosure. For example, although the present disclosure is to be described using an SRAM memory controller and one or more SRAM memory drivers, those skilled in the relevant art(s) will recognize that functions of these SRAM memory devices can be applicable to other memory devices without departing from the spirit and scope of the present disclosure.

Unless otherwise indicated, the drawings provided throughout the disclosure should not be interpreted as to-scale drawings.

### An Exemplary Memory Device

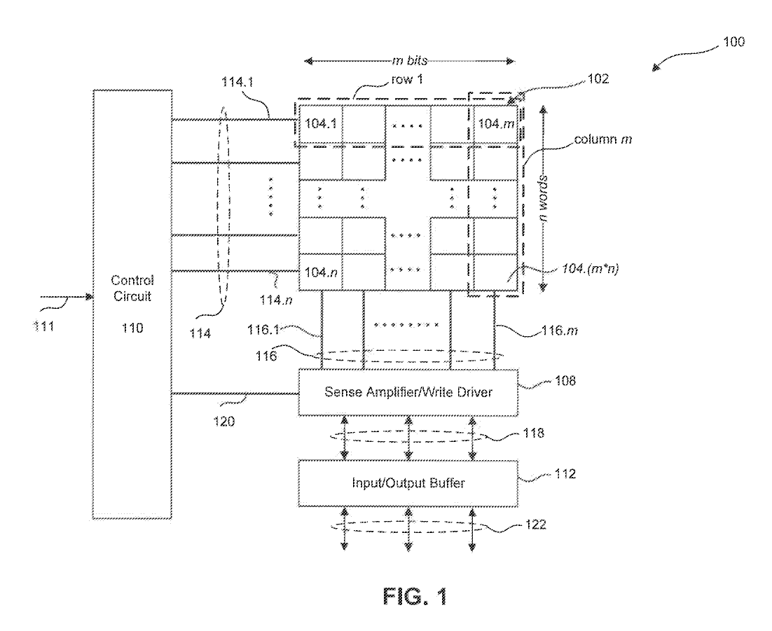

FIG. 1 illustrates a block diagram of a memory device 100 according to an example embodiment. The memory device 100 represents, for example, a non-volatile memory. As such, the memory device 100 can maintain stored electronic data even when not powered. The memory device 100 can operate in a read mode of operation to read electronic data from one or more memory cells of a memory array 102 or in a write mode of operation to write electronic data into the one or more memory cells of the memory array 102. The memory device 100 can include the memory array 102, a sense amplifier/write driver 108, a control circuit 110, an input/output (I/O) buffer 112, word lines (WLs) 114.1 through 114.n and bit lines (BLs) BLs 116.1 through 116.m.

As illustrated in FIG. 1, the memory array 102 can include memory cells 104.1 through 104.(m*n). The memory cells 104.1 through 104.(m*n) can be arranged in an array of n rows and m columns to form memory cells 104.1 through 104.(m*n). However, other arrangements for the memory cells 104.1 through 104.(m*n) are possible without departing from the spirit and scope of the present disclosure. Each of the memory cells 104.1 through 104.(m*n) can be connected to a corresponding WL from among WLs 114.1 through 114.n and a corresponding BL from among BLs 116.1 through 116.m.

In an exemplary embodiment, the memory cells 104 in each of the m columns can share a BL from among the BLs 116.1 through 116.m. Similarly, the memory cells 104 in each of n rows of the memory array 102 can share a WL from among WLs 114.1 through 114.n. For example, in FIG. 1, the memory cells 104.1. through 104.m of row 1 can share the WL 114.1 and the memory cells 104.m through 104.(m*n) of column m share BL 116.m. Even though FIG. 1 illustrates the memory cells in each of the n rows and the memory cells in each of the m columns as being connected to a single WL and a single BL, respectively, it should be noted that the disclosure is not so limiting. Each WL from among WLs 114.1 through 114.n can represent a plurality of WLs. Similarly, each BL from among BLs 116.1 through 116.m can represent a plurality of BLs.

To select a particular memory cell from among the memory cells 104.1 through 104.(m*n) for a mode of operation, such as the read mode of operation or the write mode of operation to provide some examples, the BL and the WL associated with this particular memory cell can be activated. For example, the BL 116.1 and the WL 114.1 can be activated to select the memory cell 104.1. Thereafter, the electronic data can be written into the particular memory cell in the write mode of operation or the electronic data can he read from the particular memory cell in the read mode of operation upon its selection.

Each of the WLs and the BLs can be selectively activated through the control circuit 110 that can include decoder circuitry, multiplexing circuitry, and/or latches, for example, configured to address, access, write, and/or read data to and/or from the memory array 102. The control circuit 110 can provide one or more control signals to the WLs 114.1 through 114.n that correspond to one or more memory cell access requests 111 received by the control circuit 110 to select a row of memory cells from among the memory cells 104.1 through 104.(m*n). Similarly, the control circuit 110 can provide one or more control signals 120 to the sense amplifier/write driver 108 that correspond to one or more memory cell access requests 111 received by the control circuit 110 to select a column of memory cells from among the memory cells 104.1 through 104.(m*n).

The sense amplifier/write driver 108 can read the electronic data from a memory cell that corresponds to the activated WL and BL from among the memory cells 104.1 through 104.(m*n) during a read mode operation and provides electronic data 118 to the I/O Buffer 112 in the read mode operation. The I/O Buffer 112 can store the electronic data 118 to provide electronic data 122. Alternatively, the I/O Buffer 112 can receive the electronic data 122 and provide the electronic data 122 as the electronic data 118 in the write mode of operation. Thereafter, the sense amplifier/write driver 108 can receive the electronic data 118 from the I/O Buffer 112 and can write this electronic data to the memory cell that corresponds to the activated WL and BL in the write mode of operation.

### An Exemplary Memory Cell

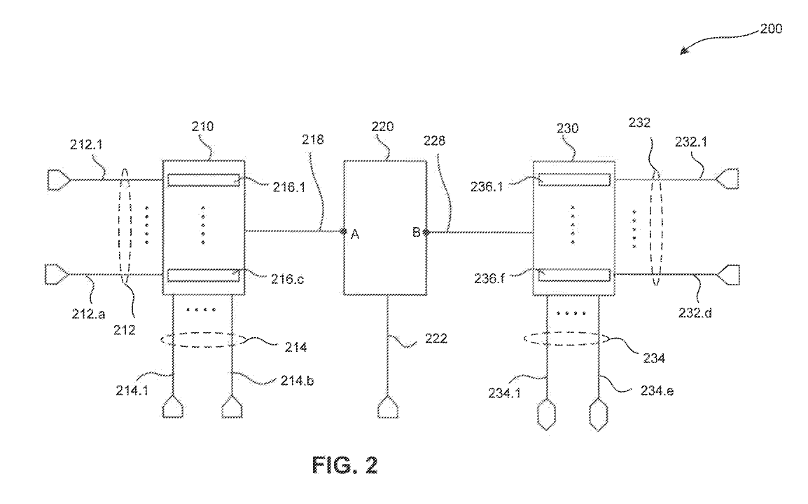

FIG. 2 illustrates a block diagram of an exemplary memory cell 200 that can be implemented as part of the memory device 100 according to an embodiment of the present disclosure. The memory cell 200 can represent one or more of the memory cells 104 of the memory cell array 102. According to an example of this embodiment, the memory cell 200 includes a write port cell 210, a storage cell 220, and a read port cell 230. The write port cell 210 can be configured to write one or more data hits into the storage cell 220, the storage cell 220 can be configured to store the one or more one or more written data bits, and the read port cell 230 can be configured to read one or more data bits that are stored in the storage cell 220.

As illustrated in FIG. 2, the write port cell 210 can include write word lines (WWLs) 212.1 through 212.a and write bit lines (WBLs) 214.1 through 214.b. The WWLs 212 and the WBLs 214 can represent one or more of the WLs 114 and one or more of the BLs 116, respectively, as discussed above in FIG. 1. The write port cell 210 can further include a plurality of write ports 216.1 through 216.c. Each of the plurality of write ports from among write port 216.1 through 216.c can be coupled to a corresponding WWL and a corresponding WBL from among WWLs 212.1 through 212.a and WBLs 214.1 through 214.b, respectively.

The plurality of write ports 216 can each be configured to independently write one or more data bits into the storage cell 220 using its corresponding pair of WWL and WBL and a control line 218. For example, to write one or more data bits (e.g., data 118 as illustrated in FIG. 1) using the write port 216.1, the WWL 212.1 can be activated using control signals (e.g., control signals from control circuit 110 as illustrated in FIG. 1) to select the write port 216.1 and one or more voltages of the WBL 214.1 corresponding to the one or more data bits can be transferred to the control line 218 through the write port 216.1.

The storage cell 220 can include an input node A to store the one or more written data bits received through the control line 218. The one or more written data bits can be stored at the input node A until replaced by a new one or more written data bits received through the control line 218 or a reset bit received as a reset control signal 222. The storage cell 220 can further include an output node B to store a complementary version of the one or more written data bits.

The read port cell 230 can include read word lines (RWLs) 232 and read bit lines (RBLs) 234, according to an example of this embodiment. The RWLs 232 and the RBLs 234 can represent one or more of the WLs 114 and one or more of the BLs 116, respectively, as illustrated in FIG. 1. The read port cell 230 can further include a plurality of write ports 236. Each of the plurality of read ports from among read ports 236.1 through 236.f can be coupled to a Corresponding RWL and a corresponding RBL from among RWLs 232.1 through 232.d and RBLs 234.1 through 234.e, respectively.

The plurality of read ports 236 can each independently and/or simultaneously read the one or more stored data bits from the storage cell 220 using its corresponding pair of RWL and RBL and a control line 228. For example, to read the one or more stored data bits using the read port 236.1, the RBL 234.1 can be precharged using a precharge circuit (not shown) to a predetermined voltage level, the RWL 232.1 can be activated using control signals (e.g., control signals from control circuit 110 as illustrated in FIG. 1) to select the read port 236.1, and one or more Voltages at the output node B corresponding to the one or more stored data bits can be transferred to the read port 236.1 through the control line 228. The voltage level of the precharged RBL 234.1 after transfer of the output node B voltage can represent the one or more data hits read from the storage cell 220.

### An Exemplary Write Port Cell that can be Implemented as a Part of The Exemplary Memory Cell

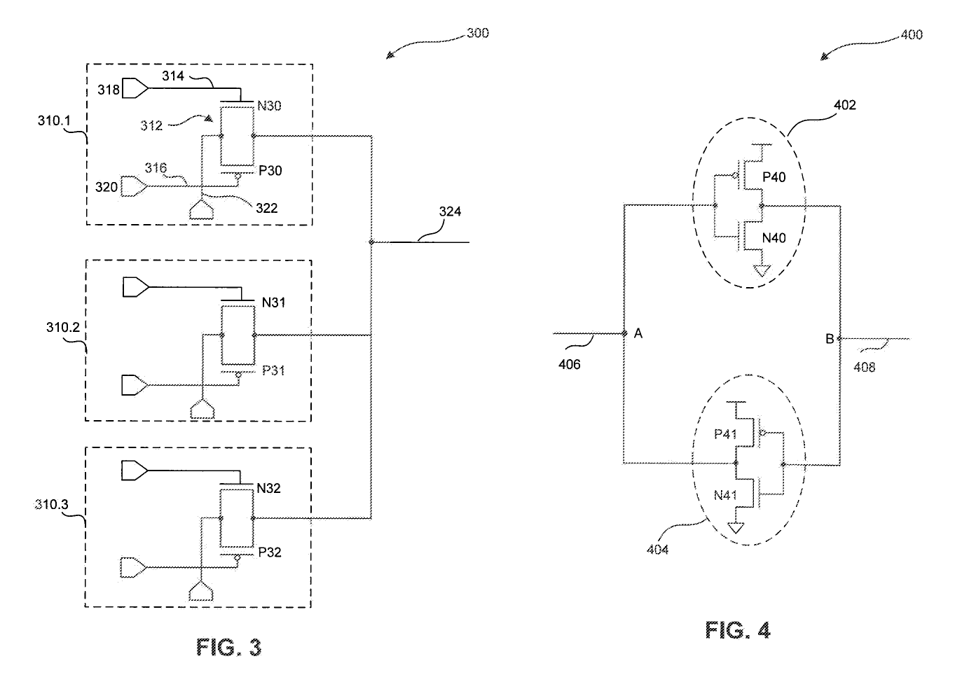

FIG. 3 illustrates a schematic diagram of a write port cell 300 that can be implemented as a part of the exemplary memory cell 200 according to an embodiment of the present disclosure. The write port cell 300 can represent an exemplary embodiment of the write port cell 210.

As illustrated in FIG. 3, the write port cell 300 can include write ports 310.1, 310.2, and 310.3. These write ports can be similar to the write ports from among write port 216.1 through 216.c. Although three write ports are illustrated in FIG. 3, the write port cell 300 can include any suitable number of the write ports having circuit configuration and functionality similar to that of the write ports 310.1, 310.2, and 310.3. For the sake of simplicity, only write port 310.1 will be described in detail.

The Write port 310.1 can he implemented using a transmission gate 312. The transmission gate 312 can include an n-channel transistor N30 and a p-channel transistor P30. The gates of the transistors N30 and P30 can he connected to control lines 314 and 316, respectively. The control line 314 can be configured to receive control signals 318 from a WWL, such as a WWL from among WWLs 212.1 through 212.a, while the control line 316 can be configured to receive control signals 320 that are complement of control signals 318. Alternatively, the control line 316 can be configured to receive control signals 320 from the WWL while the control line 314 can be configured to receive control signals 318 that are complement of control signals 320.

Additionally, the transmission gate 312 can include an input node C and an output node D. The input node C can be connected to a WBL 322, such as a WBL from among WBLs 214.1 through 214.b and the output node D can be connected to a control line 324, such as control line 218.

In order to write one or more data bits to a memory cell, such as the memory cell 200, using the write port 310.1, the transistors N30 and P30 can be turned on by the respective control signals 318 and 320 and the voltage of the WBL 322 corresponding to the one or more data bits can be transferred to the control line 324. The write ports 310.2 and 310.3 can be similarly used to write one or more data bits into the memory cell but each write port of the write port cell 300 can access the memory cell independently from each other.

It should be noted that the transistors N30 and P30 can be various types of transistors, such as metal oxide semiconductor field effect transistors (MOSFET), finFETs, bipolar junction transistors (BJTs) to provide some examples, or any other type of switching device that will be apparent to those skilled in the relevant art(s) without departing from the spirit and scope of the disclosure.

### A First Exemplary Storage Cell that can be Implemented as a Part of the Exemplary Memory Cell

FIG. 4 illustrates a schematic diagram of a storage cell 400 that can be implemented as a part of the exemplary memory cell 200, according to an embodiment of the present disclosure. The storage cell 400 can represent an exemplary embodiment of the storage cell 220.

As illustrated in FIG. 4, the storage cell 400 can be formed from a pair of inverters 402 and 404 that are arranged to be in a cross-coupled configuration. Inverter 402 can include a p-channel transistor P40 and an n-channel transistor N40 and inverter 404 can include a p-channel transistor P41 and an n-channel transistor N41. The inverter 402 output is connected to the inverter 404 input and the inverter 404 output is connected to the inverter 402 input to form the cross-coupled configuration. Thus, the inverters 402 and 404 can provide a feedback loop in the storage cell 400. The storage cell 400 can be implemented using various types of transistors such as planar transistors (e.g., MOSFETs), 3D transistors (e.g., FinFETs) or any other type of switching device that will be apparent to those skilled in the relevant art(s) without departing from the spirit and scope of the disclosure.

Additionally, the storage cell 400 can include an input node A and an output node B. The input node A can serve as an input node of the inverter 402 and also serve as an output node of the inverter 404. The output node B can serve as an output node of the inverter 402 and also serve as an input node of the inverter 404. Further, the input node A can be connected to a control line 406, such as control line 218 as illustrated in FIG. 1 and/or control line 324 as illustrated in FIG. 3 to provide some examples. The control line 406 can interface the storage cell 400 with a write port cell, such as write port cell 210 as illustrated in FIG. 1 and/or write port cell 300 as illustrated in FIG. 3 to provide some examples. The output node B can be connected to a control line 408, such as control line 228 as illustrated in FIG. 2 to provide an example. The control line 408 can interface the storage cell 400 with a read port cell, such as read port cell 230 as illustrated in FIG. 2 to provide an example.

To store one or more data bits in the storage cell 400, one or more voltages corresponding to the one or more data bits can be transferred to the input node A from a write port cell, such as write port cell 210 as illustrated in FIG. 2 and/or write port cell 300 as illustrated in FIG. 3, through the control line 406. The voltage at input node A can be retained through the feedback loop of the storage cell 400.

### A Second Exemplary Storage Cell that can be Implemented as a Part of the Exemplary Memory Cell

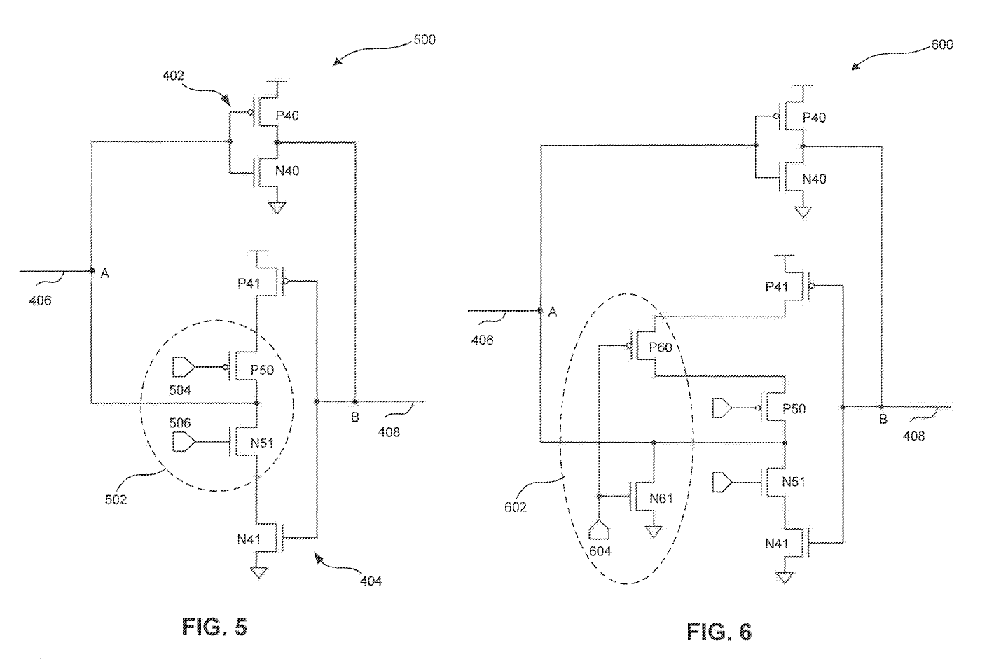

FIG. 5 illustrates a schematic diagram of a storage cell 500 that can be implemented as a part of the exemplary memory cell 200, according to an embodiment of the present disclosure. The storage cell 500 can represent an exemplary embodiment of the storage cell 220. The storage cell 500 shares many similar features with the storage cell 400, therefore only differences between the storage cell 400 and the storage cell 500 are to be discussed below.

As illustrated in FIG. 5, the storage cell 500 can additionally include a switching circuit 502 comprising a p-channel transistor P50 and an n-channel transistor N51 connected in series. The gate of the transistor P50 can be configured to receive one or more control signals 504 and the gate of the transistor N51 can be configured to receive one or more control signals 506. The control signals 504 and 506 can be provided from a control circuit, such as control circuit 110 as illustrated in FIG. 1 to provide an example. The switching circuit 502 can be implemented using various types of transistors such as planar transistors (e.g., MOSFETs), 3D transistors (e.g., FinFETs) or any other type of switching device that will be apparent to those skilled in the relevant art(s) without departing from the spirit and scope of the disclosure.

The switching circuit 502 can be configured to disable the functionality of the storage cell 500 by opening the feedback loop formed by the inverters 402 and 404. The feedback loop can be opened, for example, during a write mode of operation the memory cell 200. In order to open the feedback loop, a high voltage can be applied as the control signal 504 and a low voltage can be applied as the control signal 506. The high voltage at the transistor P50 gate can turn off the transistor P50 and the low voltage at the transistor N51 gate can turn off the transistor N51. The turned of transistors P50 and N51 can provide a non-conducting path between the transistors P41 and N41 and disable the inverter 404, which can cause the feedback loop to be opened.

It should be noted that when the feedback loop is closed, a low voltage can be provided as control signal 504 and a high voltage can be provided as control signal 506. Such voltages can keep the transistors P50 and N51 in a conducting state and can provide a conducting path between the transistors P41 and N41.

### A Third Exemplary Storage that can be Implemented as a Part of the Exemplary Memory Cell

FIG. 6 illustrates a schematic diagram of a storage cell 600 that can be implemented as a part of the exemplary memory cell 200, according to an embodiment of the present disclosure. The storage cell 600 can represent an exemplary embodiment of the storage cell 220. The storage cell 600 shares many similar features with the storage cell 500, therefore only differences between the storage cell 500 and the storage cell 600 are to be discussed below.

As illustrated in FIG. 6, the storage cell 600 can additionally include a reset circuit 602 comprising a p-channel transistor P60 and an n-channel transistor N61. The transistor P60 can be connected in series with the transistor P41 and the switching circuit 502. The transistor N61 can be connected in parallel with the transistor N51. The gates of the transistors P60 and N61 can be configured to receive one or more reset control signals 604, such as reset Control signals 222 as illustrated in FIG. 2 to provide an example. The one or more reset control signals: 604 can be provided from a control circuit, such as control circuit 110 as illustrated in FIG. 1 to provide an example. The reset circuit 602 can be implemented using various types of transistors such as planar transistors (e.g., MOSFETs), 3D transistors (e.g., FinFETs) or any other type of switching device that will be apparent to those skilled in the relevant art(s) without departing from the spirit and scope of the disclosure.

The reset circuit 602 can be configured to reset the one or more bits stored in the storage cell 600 to a logic zero. In order to reset the one or more stored bits to a logic zero, a high voltage can be applied as the control signal 604. The high voltage at the transistor P60 gate can turn off the transistor P60 and the high voltage at the transistor N61 gate can turn on the transistor N61, The turned off transistor P60 can provide a non-conducting path between the transistors P41 and N41 and disable the inverter 404, causing the feedback loop to be opened. The conducting transistor N61 can pull the voltage at input node A corresponding to the stored hit to a low voltage (e.g., ground voltage), causing the stored bit at input node A to be reset to a logic zero. It should be noted that when the reset operation is disabled, a low voltage can be provided as control signal 604.

### A Prior Art Read Port Cell

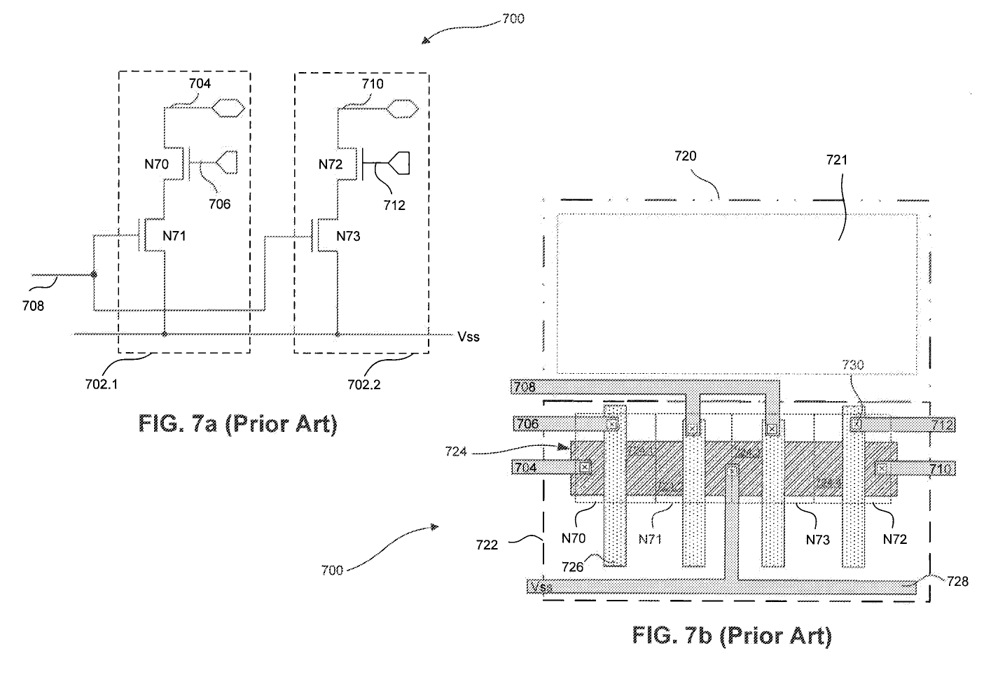

FIG. 7a illustrates a schematic diagram of a prior art read port cell. As illustrated in FIG. 7, the read port cell 700 can include read ports 702.1 and 702.2 that can be configured to read one or more data from a prior art memory cell. For the sake of simplicity, only read port 702.1 will be described in detail.

The read port 702.1 can be implemented using two n-channel transistors N70 and N71 connected in series. The drain of the transistor N70 can be connected to an RBL 704 which can be connected to a precharge circuit (not shown). The gate of the transistor N70 can be connected to an RWL 706, such as an RWL from among RWLs 232.1 through 232.d. The gate of the transistor N71 can be connected to a control line 708. The source of the transistor N71 can be connected to a supply voltage Vss (e.g., ground voltage),

In order to read one or more stored data bits from the prior art memory cell, using the read port 702.1, the RBL 704 can be precharged to a high voltage prior to reading the data. The RWL 706 can be activated to select the read port 702.1 and turn on the transistor N70 by applying a high voltage to the RWL 706. The control line 708 can transfer the voltage at an output node to the gate of the transistor N71. The voltage at the output node B corresponds to a complementary version of the stored data.

In the presence of a high voltage at the output node B (i.e., for a stored data bit of logic zero), the transistor N71 can become conducting and the RBL 704 can discharge to ground through transistors N70 and N71. The voltage of the discharged RBL 704 can be read as the voltage corresponding to the stored data of logic zero in the prior art memory cell. Alternatively, in the presence of a low voltage at the output node B (i.e. for a stored data of logic one, the transistor N71 can be non-conducting and the RBL 704 can retain the precharged high voltage, which can be read as the voltage corresponding to the stored data of logic one.

Additionally, FIG. 7a illustrates that the read ports 702.1 and 702.2 of the prior art read port cell 700 are implemented using only n-channel transistors. N-channel transistors are conventionally preferred over p-channel transistors in implementation of memory cell read ports. One of the reasons for such preference is the enhanced device performance of n-channel transistors compared to p-channel transistors, when both types of transistors are fabricated using conventional CMOS process technologies.

### A Convention Circuit Layout of the Prior Art Read Port Cell

FIG. 7b illustrates a portion of a conventional circuit layout of a prior art memory cell that includes the prior art read port cell 700. The conventional circuit layout includes a first region 720 and a second region 722. Typically, the first region 720 can be used for forming p-channel transistors of the prior art memory cell and the second region 722 can used for forming n-channel transistors of the prior art memory cell.

As illustrated in FIG. 7a, the second region 722 includes an active diffusion region 724 that can represent active diffusion regions of a semiconductor substrate upon which active regions of the transistors N70, N71, N72, and N73 as illustrated in FIG. 7a can be formed. The active diffusion region 724 can be characterized as being a combination of a first active diffusion region portion 724.1, a second active diffusion region portion 724.2, a third active diffusion region portion 724.3, and a fourth active diffusion region portion 724.4. The second region 722 further includes gate polysilicon or gate metal regions 726 illustrated using dotted shading in FIG. 7b. The gate polysilicon or gate metal regions 726 overlap the first active diffusion region portion 724,1, the second active diffusion region portion 724.2, the third active diffusion region portion 724.3, and the fourth active diffusion region portion 724.4 to form the transistors N70, N71, N73, and N72.

Additionally, the circuit layout includes metal regions 728, illustrated using solid gray shading in FIG. 7b, which represent regions of metal for routing of signals within the read port cell 700 or between the read port cell 700 and other cells of the prior art memory cell. For example, some of the metal regions 728 route a supply voltage V_{SS} to the transistors N71 and N73. As another example, some of the metal regions 728 route the control line 708 to the transistors N71 and N73, the RBL 704 and the RWL 706 to the transistor N70, and the RBL 710 and the RWL 712 to the transistor N72.

The interconnections 730, illustrated as a squared “x” in FIG. 7b, can include contacts to form interconnections between the active diffusion regions 724 and the metal regions 728 and/or between the gate polysilicon or gate metal regions 726 and the metal regions 728.

As additionally illustrated in FIG. 7b, the first region 720 includes an N-well region 721 that is part of a continuous N-well (not shown) running along the top portion of the conventional circuit layout of the prior art memory cell that includes the prior art read port cell 700. The continuous N-well is used for implementation of only p-channel transistors of the prior art memory cell. As such, the prior art read ports that are implemented using only n-channel transistors are not implemented in the first region 720 due to which the first region 720 remains unused in the conventional circuit layout of the prior art read port cell 700, as shown in FIG. 7b. Consequentially, this can lead to unused areas on chip layouts of memory devices. Reducing unused areas on chip layouts can help to shrink the size of the memory devices.

### An Exemplary Read Port Cell that can be Implemented as a Part of the Exemplary Memory Cell

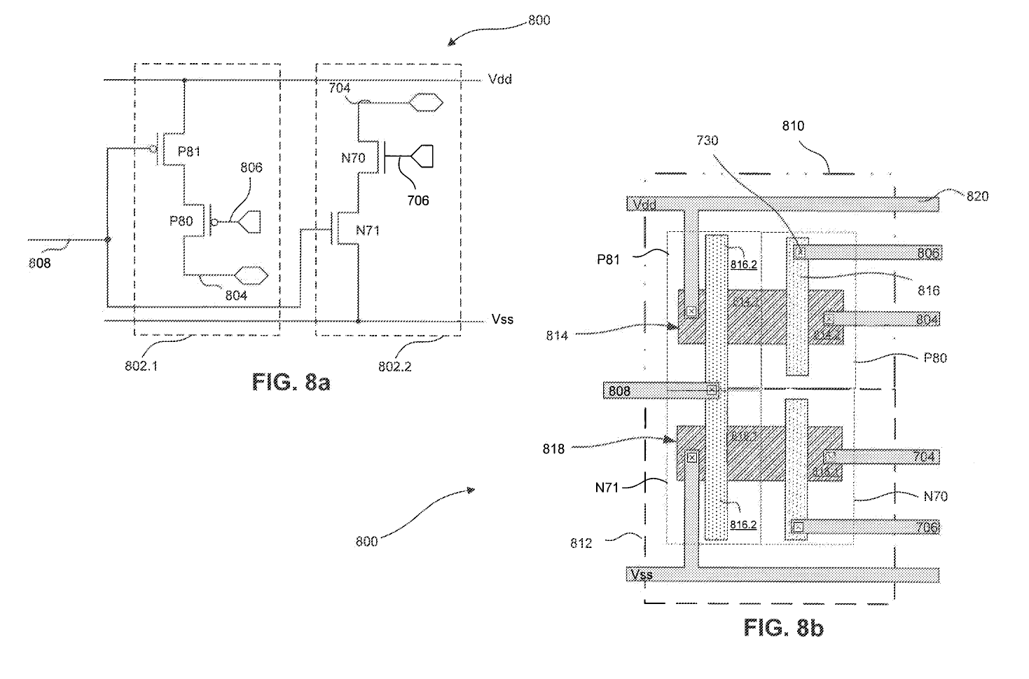

FIG. 8a illustrates a schematic diagram of a read port cell 800 that can be implemented as a part of the exemplary memory cell 200 according to an embodiment of the present disclosure. The read port cell 800 can read one or more data bits in a substantially similar manner as the read port cell 230 as illustrated in FIG. 2.

As illustrated in FIG. 8a, the read port cell 800 can include read ports 802.1 and 802.2 that can be configured to read data bits independently and/or simultaneously from the memory cell 200. The read ports 802.1 and 802.2 can each be implemented using circuit configuration different from each other, unlike the read ports 702.1 and 702.2 that are implemented using similar circuit configuration. The different read port circuit configurations can allow a memory cell having the read port cell 800 to be fabricated on a smaller chip area than that required for the fabrication of the conventional memory cell having the read port cell 700, as mentioned above.

The read ports 802.1 and 802.2 can be similar to the read ports from among read port 236.1 through 236.f as illustrated in FIG. 2. Although two read ports are illustrated in FIG. 8a, the read port cell 800 can include any suitable number of the read ports. At least half or neatly half the suitable number of read ports of read port cell 800 can have circuit configuration and functionality similar to that of the read port 802.1. The rest of the read ports of read port cell 800 can have circuit configuration and functionality similar to that of the read port 802.2.

The read port 802.2 has a circuit configuration and functionality similar to that of the read port 702.1. For the sake of simplicity, only read port 802.1 will be described in detail,

The read port 802.1 can be implemented using two p-channel transistors P80 and P81 connected in series. The transistors P80 and P81 can be various types of transistors such as planar transistors (e.g., MOSFETs), 3D transistors (e.g., FinFETs) or any other type of switching device that will be apparent to those skilled in the relevant art(s) without departing from the spirit and scope of the disclosure. The source of the transistor P80 can be connected to an RBL 804, such as an RBL from among RBLs 234.1 through 234.e as illustrated in FIG. 2, Which can be connected to a precharge circuit (not shown). The gate of the transistor P80 can be connected to an RWL 806, such as an RWL from among RWLs 232.1 through 232.d as illustrated in FIG. 2. The gate of the transistor P81 can be connected to a control line 808, such as control lines 228, 408 to provide some examples. The drain of the transistor P81 can be connected to a supply voltage Vdd.

In order to read a stored data from the memory cell 200, using the read port 802.1, the RBL 804 can be precharged to a low voltage prior to reading the data. The RWL 806 can be activated to select the read port 802.1 and turn on the transistor P80 by applying a low voltage to the RWL 806. The control line 808 can transfer the voltage at an output node, such as output node B, of a storage cell, such as storage cells 230, 400, 500, 600, to the gate of the transistor P81. The voltage at the output node B corresponds to a complementary version of the stored data.

In the presence of a low voltage at the output node B (i.e., for a stored data of logic one), the transistor P81 can become conducting and the RBL 804 can charge to the supply voltage Vdd through transistors P80 and P81. The voltage of the charged RBL 804 can be read as the voltage corresponding to the stored data of logic one in the memory cell. Alternatively, in the presence of a high voltage at the output node B (i.e., for a stored data of logic zero), the transistor P81 can be non-conducting and the RBL 804 can retain the precharged low voltage, which can be read as the voltage corresponding to the stored data of logic zero.

### An Exemplary Circuit Layout of the Exemplary Read Port Cell

FIG. 8b illustrates a circuit layout of a portion of the exemplary memory cell 200 including the read port cell 800, according to an embodiment. The circuit layout includes a first region 810 and a second region 812. Typically, the first region 810 can be used for forming p-channel transistors of the memory cell 200 as illustrated in FIG. 2 and the second region 812 can be used for forming n-channel transistors of the memory cell 200 as illustrated in FIG. 2. The combined height of the first and second regions 810 and 812 can be selected to be equal to a predefined height of standard cells in a predefined library of standard cell to allow the memory cell 200 as illustrated in FIG. 2 to be readily combined with the standard cells on, for example, an integrated circuit (IC), a semiconductor die, a chip.

As illustrated in FIG. 8b, the first region 810 includes a first active diffusion region 814 that can represent active diffusion regions of a semiconductor substrate upon which active regions of the transistors P80 and P81 can be formed. The first active diffusion region 814 can be doped with impurity atoms of an acceptor type, such as boron or aluminum. The first active diffusion region 814 can be characterized as being a combination of a first active diffusion region portion 814.1 and a second active diffusion region portion 814.2. The gate polysilicon or gate metal regions 816 overlap the first active diffusion region portion 814.1 and the second active diffusion region. portion 814.2 to form the transistors P81 and P80.

The second region 812 includes a second active diffusion region 818 that can represent active diffusion regions of a semiconductor substrate upon Which active regions of the transistors N70 and N71 can be formed. The second active diffusion region 818 can be doped with impurity atoms of the donor type. The second active diffusion region 818 can be characterized as being a combination of a third active diffusion region portion 818.1 and a fourth active diffusion region portion 818.2. The gate polysilicon or gate metal regions 816 overlap the third active diffusion region portion 818.1 and the fourth active diffusion region portion 818.2 to form the transistors N71 and N70.

Additionally, the circuit layout includes metal regions 820, illustrated. using solid gray shading in FIG. 8b, which represent regions of metal for routing of signals within the read port cell 800 or between the read port cell 800 and other cells of the memory cell 200. The interconnections 822, illustrated as a squared “x” in FIG. 8b, can include contacts to form interconnections between the first active diffusion regions 814 and the metal regions 822, the second active diffusion regions 818 and the metal regions 822, and/or between the gate polysilicon or gate metal regions 816 and the metal regions 820.

In an exemplary embodiment, the transistor N71 and P81 can share a common gate polysilicon or gate metal region 816 with a first portion 816.1 overlapping the first active diffusion region portion 814.1 and a second portion 816.2 overlapping the third active diffusion region portion 818.1. In other situations, the transistor N71 and PSI can share a common. metal region 820. However, other circuit layouts for the read port cell 800 are possible as will be apparent to those skilled in the relevant art(s) without departing from the spirit and scope of the present disclosure.

The circuit layout of FIG. 8b illustrates that implementing the read ports 802.1 and 802.2 with both types of transistors can help to reduce unused area in the chip layouts of memory devices compared to the area needed for implementing read ports 702.1 and 702.2, as discussed above. Also, reducing the unused chip layout area can reduce the overall layout area of the memory device. According to an embodiment, such reduction of unused chip layout area can be achieved when the n-channel and p-channel transistors exhibit comparable device performances, such as shown by n-channel and p-channel transistors fabricated using, finFET process technology, to provide an example.

### CONCLUSION

It is to be appreciated that the Detailed Description section, and not the Abstract section, is intended to be used to interpret the claims. The Abstract section can set forth one or more, but not all exemplary embodiments, of the present disclosure, and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein tor the convenience of the description. Alternate boundaries can be defined so long as the specified functions and relationships thereof are appropriately performed.

It will be apparent to those skilled in the relevant art(s) that various changes in form and detail can be made therein without departing from the spirit and scope of the present disclosure. Thus, the present disclosure should not be limited by any of the above-described exemplary embodiments, but should be defined only in accordance with the following claims and their equivalents.

What is claimed is:

1. A memory cell, comprising:
a storage cell configured to store a logic value;
a write port cell coupled to the storage cell configured to write the logic value; and
a read port cell coupled to the storage cell configured to read the stored logic value, the read port cell comprising a plurality of read ports,
wherein a first read port of the plurality of read ports includes a first p-channel transistor and a second p-channel transistor, and
wherein a second read port of the plurality of read ports includes a first n-channel transistor and a second n-channel transistor.

2. The memory cell of claim 1, wherein a first portion of the plurality of read ports each includes the first p-channel transistor and the second p-channel transistor, and
wherein a second portion of the plurality of read ports each includes the first n-channel transistor and the second n-channel transistor.

3. The memory cell of claim 1, wherein the first and the second p-channel transistors and the first and the second n-channel transistors are fin field effect transistors (FinFETs).

4. The memory cell of claim 1, wherein the first and the second p-channel transistors and the first and the second n-channel transistors are metal-oxide-semiconductor field effect transistors (MOSFETs).

5. The memory cell of claim 1, wherein gates of the first p-channel transistor and the first n-channel transistor are coupled to an output node of the storage cell.

6. The memory cell of claim 1, wherein the second p-channel transistor is coupled to a first read bit line (RBL) and a first read word line (RWL), and
wherein the second n-channel transistor is coupled to a second RBL and a second RWL.

7. The memory cell of claim 6, wherein the first RBL is configured to be precharged to a first voltage level, and
wherein the second RBL is configured to be precharged to a second voltage level, the second voltage level being different from the first voltage level.

8. The memory cell of claim 1, wherein the storage cell comprises:
a feedback loop; and
a switching circuit configured to open the feedback loop during a write mode of operation.

9. The memory cell of claim 1, wherein the storage cell comprises:
a feedback loop: and
a reset circuit configured to:
open the feedback loop; and
set a logic value at an input node of the storage cell.

10. A memory cell, comprising:
a storage cell configured to store a logic value;
a write port cell, coupled to the storage cell, configured to write the logic value; and
a read port cell, coupled to the storage cell, configured to read the stored logic value, the read port cell comprising a plurality of read ports,
wherein a first read port of the plurality of read ports includes a first active diffusion region and a second active diffusion region, the first active diffusion region being configured to be used for implementation of a first p-channel transistor and the second active diffusion region being configured to be used for implementation of a second p-channel transistor, and
wherein a second read port of the plurality of read ports includes a third active diffusion region and a fourth active diffusion region, the third active diffusion region being configured to be used for implementation of a first n-channel transistor and the second active diffusion region being configured to be used for implementation of a second n-channel transistor.

11. The memory cell of claim 10, wherein the first and the second active diffusion regions are configured to form a first substantially continuous active diffusion region, and
wherein the third and the fourth active diffusion regions are configured to form a second substantially continuous active diffusion region.

12. The memory cell of claim 10, wherein the first and the second p-channel transistors and the first and the second n-channel transistors are metal-oxide-semiconductor field effect transistors (MOSFETs).

13. The memory cell of claim 10, wherein the first and the second p-channel transistors and the first and the second n-channel transistors are fin field effect transistors (FinFETs).

14. The memory cell of claim 10, wherein a first portion of the plurality of read ports each includes the first p-channel transistor and the second p-channel transistor, and
wherein a second portion of the plurality of read ports each includes the first n-channel transistor and the second n-channel transistor.

15. The memory cell of claim 10, wherein the first portion of the plurality of read ports each further includes a first polysilicon region, the first polysilicon region being configured as a first gate region of the first p-channel transistor, and
wherein the second portion of the plurality of read ports each further includes a second polysilicon region, the second polysilicon region being configured as a second gate region of the first n-channel transistor.

16. The memory cell of claim 15, wherein the first and the second polysilicon regions are configured to form a substantially continuous polysilicon region.

17. A semiconductor device, comprising:
a storage cell configured to store a logic value;
a write port cell configured to write the logic value; and
a read port cell configured to read the stored logic value, the read port cell comprising a first read port and a second read port,
wherein the first read port includes a first active diffusion region and a second active diffusion region, the first active diffusion region being configured to be used for implementation of a first p-channel transistor and the second active diffusion region being configured to be used for implementation of a second p-channel transistor, and
wherein the second read port includes a third active diffusion region and a fourth active diffusion region, the third active diffusion region being configured to be used for implementation of a first n-channel transistor and the second active diffusion region being configured to be used for implementation of a second n-channel transistor.

18. The semiconductor device of claim 17, wherein the first read port further includes a first polysilicon region, the first polysilicon region being configured as a first gate region of the first p-channel transistor, and
wherein the second read port further includes a second polysilicon region, the second polysilicon region being configured as a second gate region of the first n-channel transistor.

19. The semiconductor device of claim 18, wherein the first and the second polysilicon regions are configured to form a substantially continuous polysilicon region.

20. The semiconductor device of claim 17, wherein the first and the second p-channel transistors and the first and second n-channel transistors are fin field effect transistors (FinFETs).
